(19) United States
(12) Patent Application Publication
(10) Pub. No.: US 2025/0140141 A1
(43) Pub. Date: May 1, 2025

(54) TEST CIRCUIT AND DISPLAY DEVICE INCLUDING THE SAME

(71) Applicant: Samsung Display Co., LTD., Yongin-si (KR)

(72) Inventors: EOK SU KIM, Yongin-si (KR); SOYOUNG KOO, Yongin-si (KR); JONGDO KEUM, Yongin-si (KR); HYUNGJUN KIM, Yongin-si (KR); GEUNCHUL PARK, Yongin-si (KR)

(21) Appl. No.: 18/926,720

(22) Filed: Oct. 25, 2024

(30) Foreign Application Priority Data
Nov. 1, 2023 (KR) 10-2023-0149165

(51) Int. Cl. G09G 3/00; G09G 3/3266; H10K 59/131

(52) U.S. Cl. CPC G09G 3/006; G09G 3/3266; H10K 59/131; G09G 2300/0426; G09G 2330/12

(57) ABSTRACT

A test circuit includes: a metal pattern disposed in a first area; a test gate driver disposed in a second area adjacent to the first area and including a plurality of test stages, each of which outputs a test gate signal; and a plurality of test gate lines overlapping the metal pattern in a plan view, connected to the plurality of test stages, respectively, each including a first metal line and a second metal line connected in series with the first metal line, and which receives the test gate signal.

This application claims priority to Korean Patent Application No. 10-2023-0149165, filed on Nov. 1, 2023, and all the benefits accruing therefrom under 35 U.S.C. § 119, the content of which in its entirety is herein incorporated by reference.

### BACKGROUND

### 1. Technical Field

Embodiments provide generally to a display device. More particularly, embodiments relate to a test circuit for evaluating the driving ability of a gate driver and a display device including the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

Meanwhile, at least one test circuit may be disposed in a non-display area of the display device. The driving ability of a gate driver disposed in the non-display area can be evaluated through the test circuit. The test circuit may be removed and not remain in a final product, or the test circuit may not be removed and remain in the final product.

### SUMMARY

Embodiments provide a test circuit capable of implementing a waveform substantially equivalent to a gate signal applied to a pixel.

Embodiments provide a display device including the test circuit.

A test circuit according to embodiments of the present disclosure includes: a metal pattern disposed in a first area; a test gate driver disposed in a second area adjacent to the first area and including a plurality of test stages, each of which outputs a test gate signal; and a plurality of test gate lines overlapping the metal pattern in a plan view, connected to the plurality of test stages, respectively, each including a first metal line and a second metal line connected in series with the first metal line, and which receives the test gate signal.

In an embodiment, a resistance of the second metal line may be greater than a resistance of the first metal line.

In an embodiment, the first metal line may include a relatively low-resistance metal material compared to the second metal line.

In an embodiment, the second metal line may include a metal oxide semiconductor.

In an embodiment, the first metal line may be directly connected to each of the plurality of test stages.

In an embodiment, the second metal line may include a metal oxide semiconductor doped with an N-type impurity.

In an embodiment, the first metal line may be connected to the second metal line through a contact hole.

In an embodiment, the first metal line may be adjacent to the second metal line in a first direction, a first width of a part of the first metal line overlapping the metal pattern may be the same as a second width of the second metal line, and the first width and the second width may be measured in a second direction crossing the first direction.

In an embodiment, a first length of the part of the first metal line overlapping the metal pattern may be different from a second length of the second metal line, and the first length and the second length may be measured in the first direction.

In an embodiment, the first length may be longer than the second length.

In an embodiment, the first length may be shorter than the second length.

In an embodiment, the metal pattern may include a plurality of sub-patterns connected to each other and overlapping the plurality of test gate lines in the plan view, respectively.

In an embodiment, the metal pattern may include a plurality of sub-patterns connected to each other, overlapping the plurality of test gate lines in the plan view, respectively, and arranged along a first direction. A plurality of openings arranged along a second direction crossing the first direction may be defined in each of the plurality of sub-patterns in the plan view.

A test circuit according to embodiments of the present disclosure includes: a metal pattern disposed in a first area; a test gate driver disposed in a second area adjacent to the first area and including a plurality of test stages, each of which outputs a test gate signal; and a plurality of test gate lines overlapping the metal pattern in a plan view, connected to the plurality of test stages, respectively, each having a zigzag shape in the plan view and which receives the test gate signal.

In an embodiment, the metal pattern may include a plurality of sub-patterns connected to each other and overlapping the plurality of test gate lines in the plan view, respectively.

In an embodiment, the metal pattern may include a plurality of sub-patterns connected to each other, overlapping the plurality of test gate lines in the plan view, respectively, and arranged along a first direction. A plurality of openings arranged along a second direction crossing the first direction may be defined in each of the plurality of sub-patterns in the plan view.

A display device according to embodiments of the present disclosure includes: a display panel including a display area in which a plurality of pixels are disposed, and a non-display area surrounding at least a part of the display area and including a first test area; a gate driver disposed in the non-display area and, which applies a gate signal to the plurality of pixels; and a first test circuit disposed in the first test area and including: a first metal pattern disposed in a first area of the first test area, a first test gate driver disposed in a second area of the first test area adjacent to the first area and including a plurality of test stages, each of which outputs a first test gate signal; and a plurality of first test gate lines overlapping the first metal pattern in a plan view, connected to the plurality of test stages, respectively each including a first metal line and a second metal line connected in series with the first metal line, and which receives the first test gate signal.

In an embodiment, the first metal line may be directly connected to each of the plurality of test stages and the second metal line may include a metal oxide semiconductor.

In an embodiment, the first metal line may be connected to the second metal line through a contact hole.

In an embodiment, the display device may further include: a second test circuit disposed in a second test area positioned in the non-display area and including a third area and a fourth area, and including: a second metal pattern disposed in the third area of the second test area, a second test gate driver disposed in the fourth area of the second test area adjacent to the third area and including a plurality of test stages, each of which outputs a second test gate signal, and a plurality of test gate lines overlapping the second metal pattern in the plan view, connected to the plurality of test stages of the second test gate driver, respectively, each having a zigzag shape in the plan view, and which receives the second test gate signal.

A test circuit according to embodiments of the present disclosure may include a plurality of test gate lines connected to a test gate driver and that receives a test gate signal, and each including a first metal line and a second metal line connected in series with the first metal line. Alternatively, each of the plurality of test gate lines may have a zigzag shape in a plan view. Accordingly, a load corresponding to resistance and capacitance substantially equivalent to a display area may be reflected in the test circuit. In this case, it can be possible to implement a waveform of the test gate signal that is substantially equivalent to a gate signal applied to a pixel.

### BRIEF DESCRIPTION OF THE DRAWINGS

Illustrative, non-limiting embodiments will be more clearly understood from the following detailed description in conjunction with the accompanying drawings.

FIG. 1 is a block diagram schematically illustrating a display device according to an embodiment of the present disclosure.

FIG. 2 is a circuit diagram illustrating one pixel included in the display device of FIG. 1.

FIG. 3 is a view illustrating a gate driver of FIG. 1.

FIG. 4 is a cross-sectional view taken along line I-I′ of FIG. 1.

FIG. 5 is a plan view illustrating an example of a test circuit disposed in a test area of FIG. 1.

FIG. 6 is a view illustrating a test gate driver of FIG. 5.

FIG. 7 is a graph illustrating waveform of a test gate signal applied to each of the first and second test gate pads of FIG. 5.

FIG. 8 is a cross-sectional view illustrating an example of a cross-section taken along line II-II′ of FIG. 5.

FIG. 9 is a cross-sectional view illustrating another example of a cross-section taken along line II-II′ of FIG. 5.

FIG. 10 is a plan view illustrating another example of a test circuit disposed in a test area of FIG. 1.

FIG. 11 is a plan view illustrating still another example of a test circuit disposed in a test area of FIG. 1.

FIG. 12 is a plan view for explaining a test gate line of FIG. 11.

FIG. 13 is a plan view illustrating still another example of a test circuit disposed in a test area of FIG. 1.

FIG. 14 is a block diagram schematically illustrating a display device according to another embodiment of the present disclosure.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present. Hereinafter, a test circuit and a display device including the same according to embodiments of the present disclosure will be explained in detail with reference to the accompanying drawings. The same reference numerals are used for the same components in the drawings, and redundant descriptions of the same components will be omitted.

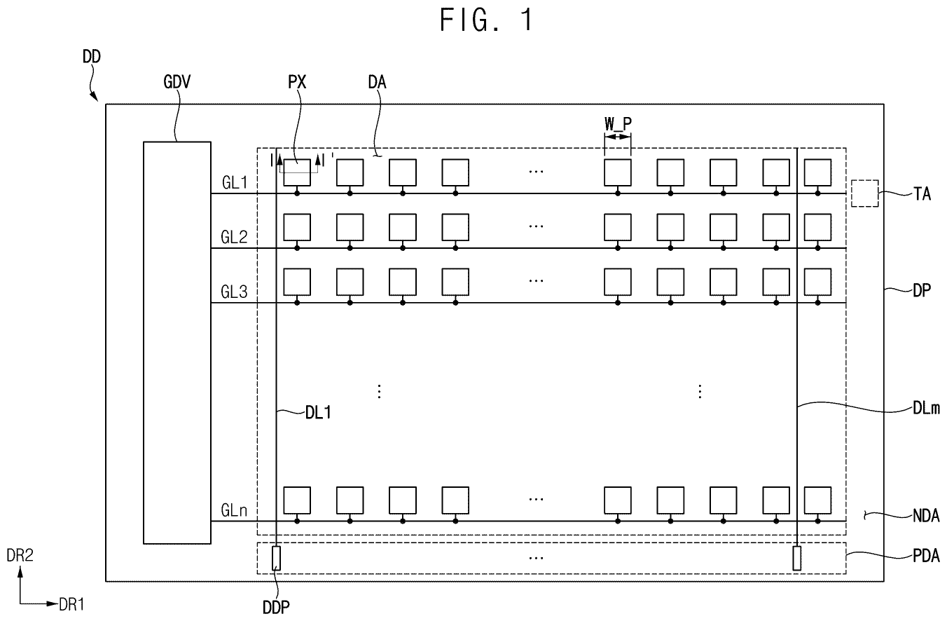

FIG. 1 is a block diagram schematically illustrating a display device according to an embodiment of the present disclosure.

Referring to FIG. 1, a display device DD according to an embodiment of the present disclosure may include a display panel DP, a plurality of data pads DDP, a plurality of data lines DL1 to DLm, a gate driver GDV, a plurality of gate lines GL1 to GLn, and a plurality of pixels PX (where each of n and m is natural number greater than 1).

The display panel DP may include a display area DA and a non-display area NDA. The display area DA may be an area that can display an image by generating light or adjusting the transmittance of light provided from an external light source. The non-display area NDA may be an area that does not display images. The non-display area NDA may be positioned around the display area DA. For example, the non-display area NDA may entirely surround the display area DA.

A plurality of pixels PX may be arranged in the display area DA. Each of the plurality of pixels PX may emit light to the outside of the display device DD through a light emitting element. For example, the plurality of pixels PX may be disposed in a matrix form along a first direction DR1 and a second direction DR2 crossing the first direction DR1.

Each of the plurality of pixels PX may emit light having one preset color. For example, the plurality of pixels PX may include a first pixel that emits first light, a second pixel that emits second light, and a third pixel that emits third light. For example, the first light may be red light, the second light may be green light, and the third light may be blue light. However, embodiments of the present disclosure are not limited thereto. For example, the first, second, and third pixels may be combined to emit yellow, cyan, and magenta lights.

The first, second, and third pixels may emit light of four or more colors. For example, the first to third pixels may be combined to emit at least one of yellow, cyan, and magenta lights in addition to red, green, and blue lights. In addition, the first, second, and third pixels may be combined to emit more white light.

The plurality of gate lines GL1 to GLn and the plurality of data lines DL1 to DLm may be disposed in the display area DA. The plurality of gate lines GL1 to GLn may be electrically connected to the plurality of pixels PX and may provide a gate signal to the plurality of pixels PX, respectively. The plurality of data lines DL1 to DLm may be electrically connected to the plurality of pixels PX and may provide a data voltage to the plurality of pixels PX, respectively. In addition, a plurality of power lines that provide power to the plurality of pixels PX may be further disposed in the display area DA.

The plurality of gate lines GL1 to GLn may be sequentially disposed along the second direction DR2. In addition, each of the plurality of gate wires GL1 to GLn may extend in the first direction DR1. The plurality of data lines DL1 to DLm may be sequentially arranged along the first direction DR1. In addition, each of the plurality of data lines DL1 to DLm may extend in the second direction DR2.

A driver for generating a driving signal may be disposed in the non-display area NDA. For example, the driver may include the gate driver GDV that generates a gate signal. The plurality of gate lines GL1 to GLn may be electrically connected to the gate driver GDV. Accordingly, the gate driver GDV may apply the gate signal to the plurality of gate lines GL1 to GLn. A detailed description of the gate driver GDV will be provided later.

The non-display area NDA may include a pad area PDA. The pad area PDA may be positioned away from one side of the display area DA. For example, the pad area PDA may have a shape extending in the first direction DR1.

The plurality of data pads DDP may be disposed in the pad area PDA. Specifically, the plurality of data pads DDP may be disposed along the first direction DR1. The plurality of data pads DDP may be electrically connected to the plurality of data lines DL1 to DLm, respectively. Accordingly, the plurality of data pads DDP may provide the data voltage to the plurality of pixels PX through the plurality of data lines DL1 to DLm, respectively. For example, each of the plurality of data pads DDP may include metal, alloy, metal nitride, conductive metal oxide, transparent conductive material, and the like. These can be used alone or in combination with each other.

A driving apparatus may be bonded to the plurality of data pads DDP. Because of this, the plurality of data lines DL1 to DLm may receive a driving signal (e.g., the data voltage and the like) from the driving device. For example, the driving apparatus may be a printed circuit board (PCB) or a flexible printed circuit board (FPCB) on which a driving chip is mounted. Alternatively, the driving apparatus may be electrically connected to the pad area PDA and the data pads DDP through a connection member such as a flexible circuit film.

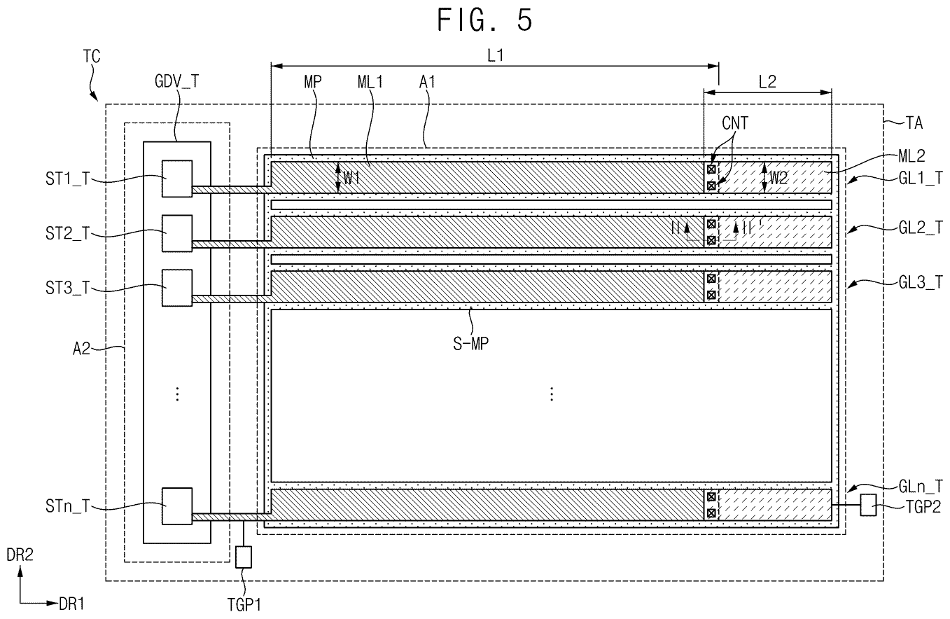

The non-display area NDA may further include at least one test area TA. The test area TA may be positioned away from one side of the display area DA. The location of the test area TA shown in FIG. 1 is illustrative, and embodiments of the present disclosure are not limited thereto. A test circuit (e.g., a test circuit TC of FIG. 5) that evaluates the driving capability of the gate driver GDV may be disposed in the test area TA. A detailed description of the test circuit will be provided later. As shown in FIG. 1, there may be one test area TA. Alternatively, there may be a plurality of test areas TA.

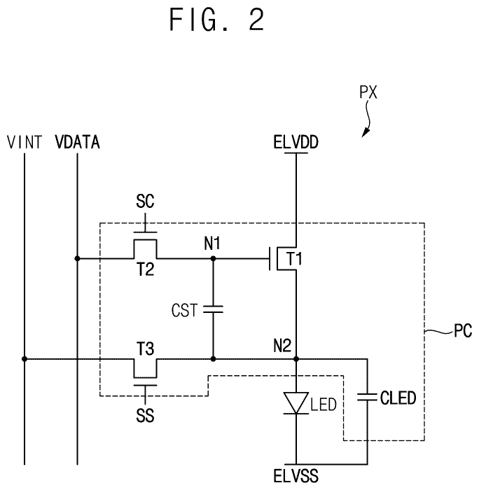

The test circuit disposed in the test area TA may be removed from the display device DD after the manufacturing process of the display device DD. Alternatively, the test circuit disposed in the test area TA may remain in the display device DD without being removed from the display device DD after the manufacturing process of the display device DD. FIG. 2 is a circuit diagram illustrating one pixel included in the display device of FIG. 1.

Referring to FIG. 2, the pixel PX may include a pixel circuit PC and a light emitting element LED electrically connected to the pixel circuit PC. Here, the pixel circuit PC may include first, second, and third transistors T1, T2, and T3, a storage capacitor CST, and a light emitting capacitor CLED.

The first transistor T1 may include a first electrode, a gate electrode, and a second electrode. The gate electrode of the first transistor T1 may be connected to a first node N1. A driving voltage ELVDD may be applied to the first electrode of the first transistor T1. The second electrode of the first transistor T1 may be connected to a second node N2. The first transistor T1 may receive the driving voltage ELVDD from a driving voltage line in response to the voltage of a first node N1 and supply a driving current to the light emitting element LED. For example, the first transistor T1 may be a driving transistor for driving the light emitting element LED.

The second transistor T2 may include a first electrode, a gate electrode, and a second electrode. A first gate signal SC may be applied to the gate electrode of the second transistor T2. A data voltage VDATA may be applied to the first electrode of the second transistor T2. The second electrode of the second transistor T2 may be connected to the first node N1. The second transistor T2 may be turned on by the first gate signal SC to electrically connect a data line that provides the data voltage VDATA to the first node N1. For example, the second transistor T2 may be a switching transistor.

The third transistor T3 may include a first electrode, a gate electrode, and a second electrode. A second gate signal SS may be applied to the gate electrode of the third transistor T3. An initialization voltage VINT may be applied to the first electrode of the third transistor T3. The second electrode of the third transistor T3 may be connected to the second node N2. The third transistor T3 may be turned on by the second gate signal SS to electrically connect an initialization voltage line that provides the initialization voltage VINT to the second node N2. For example, the third transistor T3 may be an initialization transistor.

The storage capacitor CST may include a first electrode and a second electrode. The first electrode of the storage capacitor CST may be connected to the first node N1. The second electrode of the storage capacitor CST may be connected to the second node N2. The storage capacitor CST may store the difference voltage between a gate voltage and a source voltage of the first transistor T1.

The light emitting capacitor CLED may include a first electrode and a second electrode. The first electrode of the light emitting capacitor CLED may be connected to the second node N2. The second electrode of the light emitting capacitor CLED may be connected to the second electrode of the light emitting element LED. As the light emitting capacitor CLED can maintain the voltage across both ends of the light emitting element LED constant, thereby allowing the light emitting element LED to display constant luminance. Alternatively, the light emitting capacitor CLED may be omitted.

The light emitting element LED may include a first electrode (e.g., an anode electrode) and a second electrode (e.g., a cathode electrode). The first electrode of the light emitting element LED may be connected to the second node N2. A common voltage ELVSS may be applied to the second electrode of the light emitting element LED. The light emitting element LED may emit light with a luminance corresponding to the driving current provided from the pixel circuit PC.

However, in FIG. 2, one pixel PX is shown as including three transistors T1, T2, and T3, one storage capacitor CST, and one light emitting capacitor CLED, but embodiments of the present disclosure are not limited thereto.

In addition, in FIG. 2, one pixel PX is shown as including one light emitting element LED, but embodiments of the present disclosure are not limited thereto. For example, one pixel PX may include two or more light emitting elements.

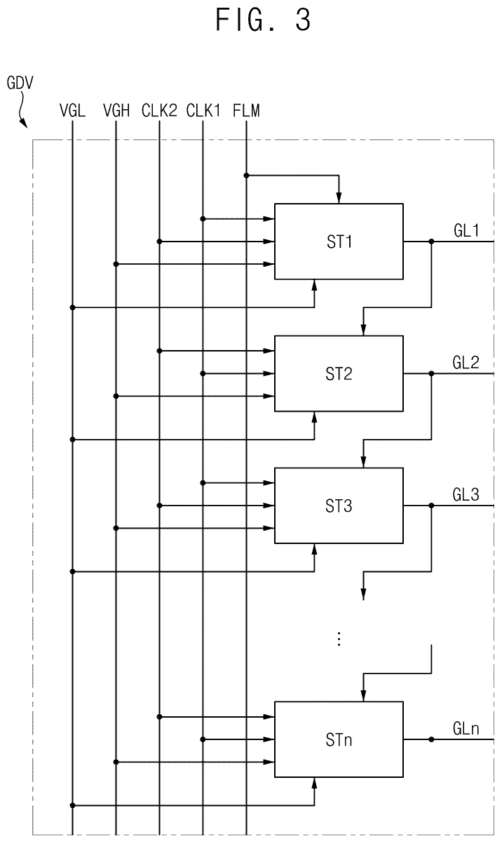

FIG. 3 is a view illustrating a gate driver of FIG. 1.

Referring to FIG. 3, the gate driver GDV may include a plurality of stages ST1 to STn. For example, the plurality of stages ST1 to STn may be connected to the plurality of gate lines GL1 to GLn, respectively (where n is a natural number greater than 1).

The plurality of stages ST1 to STn may output a plurality of gate signals in response to a first voltage VGL, a second voltage VGH, at least one clock signal CLK1 and CLK2, and a gate start signal FLM. The plurality of gate signals may be applied to the plurality of gate lines GL1 to GLn, respectively. The gate start signal FLM may be applied to the first stage ST1.

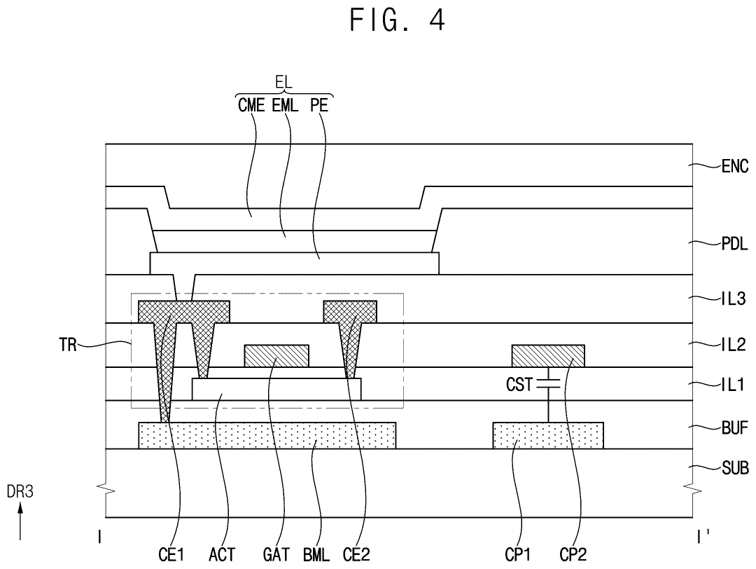

FIG. 4 is a cross-sectional view taken along line I-I′ of FIG. 1. For example, FIG. 4 is a view illustrating a cross-section of one pixel PX of FIG. 1.

Referring to FIG. 4, the display device DD may include a substrate SUB, a lower metal layer BML, a first conductive pattern CP1, a buffer layer BUF, a transistor TR, a second conductive pattern CP2, a first conductive pattern CP1, first, second, and third insulating layers IL1, IL2, and IL3, a pixel defining layer PDL, a light emitting element EL, and an encapsulation layer ENC.

Here, the transistor TR may include an active layer ACT, a gate electrode GAT, a first electrode CE1, and a second electrode CE2, and the light emitting element EL may include a pixel electrode PE, a light emitting layer EML, and a common electrode CME.

The substrate SUB may include a transparent material or an opaque material. The substrate SUB may be made of a transparent resin substrate. Examples of the transparent resin substrate may include a polyimide substrate. In this case, the polyimide substrate may include a first organic layer, a first barrier layer, a second organic layer, and the like. Alternatively, the substrate SUB may include a quartz substrate, synthetic quartz substrate, calcium fluoride substrate, F-doped quartz substrate, a soda-lime glass substrate, a non-alkali glass substrate, and the like. These can be used alone or in combination with each other.

The lower metal layer BML may be disposed on the substrate SUB. The lower metal layer BML may overlap the active layer ACT in the plan view. The lower metal layer BML may prevent light from being incident on the active layer ACT or may be electrically connected to the active layer ACT to stabilize the electrical characteristics of the transistor TR. For example, the lower metal layer BML may include metal, alloy metal nitride, conductive metal oxide, transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide, indium zinc oxide, and the like. In addition, examples of the metal nitride may include aluminum nitride (AlNₓ), tungsten nitride (WNₓ), chromium nitride (CrNₓ), and the like. These can be used alone or in combination with each other.

The first conductive pattern CP1 may be disposed on the substrate SUB. The first conductive pattern CP1 may be disposed in the same layer as the lower metal layer BML. That is, the first conductive pattern CP1 may be formed using the same material as the lower metal layer BML and through the same process as the lower metal layer BML.

The buffer layer BUF may be disposed on the substrate SUB. In addition, the buffer layer BUF may cover the lower metal layer BML and the first conductive pattern CP1. The buffer layer BUF may prevent metal atoms or impurities from diffusing from the substrate SUB to the transistor (e.g., the transistor TR). In addition, the buffer layer BUF can improve the flatness of the surface of the substrate SUB when the surface of the substrate SUB is not uniform. For example, the buffer layer BUF may include an inorganic material such as silicon oxide, silicon nitride, silicon oxynitride, and the like. These can be used alone or in combination with each other.

The active layer ACT may be disposed on the buffer layer BUF. The active layer ACT may include a metal oxide semiconductor, an inorganic semiconductor (e.g., amorphous silicon, poly silicon), or an organic semiconductor. The active layer ACT may include a source region, a drain region, and a channel region positioned between the source region and the drain region.

The metal oxide semiconductor may include a binary compound (ABₓ), a ternary compound (ABₓC_{y}), a quaternary compound (ABₓC_{y}D_{z}), and the like containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and the like. These can be used alone or in combination with each other.

The first insulating layer IL1 may be disposed on the buffer layer BUF. Additionally, the first insulating layer IL1 may cover the active layer ACT. For example, the first insulating layer IL1 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These can be used alone or in combination with each other.

The gate electrode GAT may be disposed on the first insulating layer IL1. The gate electrode GAT may overlap the channel region of the active layer ACT in the plan view. For example, the gate electrode GAT may include metal, alloy metal nitride, conductive metal oxide, transparent conductive material, and the like. These can be used alone or in combination with each other.

The second conductive pattern CP2 may be disposed on the first insulating layer IL1. In addition, the second conductive pattern CP2 may overlap the first conductive pattern CP1 in the plan view. The second conductive pattern CP2 may form the storage capacitor CST together with the first conductive pattern CP1. The storage capacitor CST of FIG. 4 may correspond to the storage capacitor CST of FIG. 2. The second conductive pattern CP2 may be disposed in the same layer as the gate electrode GAT. That is, the second conductive pattern CP2 may be formed using the same material as the gate electrode GAT and through the same process as the gate electrode GAT.

The second insulating layer IL2 may be disposed on the first insulating layer IL1 and the gate electrode GAT. The second insulating layer IL2 may cover the gate electrode GAT. For example, the second insulating layer IL2 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These can be used alone or in combination with each other.

The first electrode CE1 and the second electrode CE2 may be disposed on the second insulating layer IL2. The first electrode CE1 may be connected to the source region of the active layer ACT through a first contact hole penetrating the first insulating layer IL1 and the second insulating layer IL2. In addition, the first electrode CE1 may be connected to the lower metal layer BML through a first contact hole penetrating the first insulating layer IL1, the second insulating layer IL2, and the buffer layer BUF. Accordingly, the transistor TR may be electrically connected to the lower metal layer BML. The second electrode CE2 may be connected to the drain region of the active layer ACT through a third contact hole penetrating the first and second insulating layers IL1 and IL2.

For example, each of the first electrode CE1 and the second electrode CE2 may include metal, alloy metal nitride, conductive metal oxide, transparent conductive material, and the like. These can be used alone or in combination with each other.

The third insulating layer IL3 may be disposed on the second insulating layer IL2. The third insulating layer IL3 may sufficiently cover the first electrode CE1 and the second electrode CE2. In addition, the third insulating layer IL3 may have a substantially flat upper surface. The third insulating layer IL3 may include an inorganic material or an organic material. In an embodiment, the third insulating layer IL3 may include an organic material. For example, the third insulating layer IL3 may include an organic material such as phenolic resin, polyacrylates resin, polyimides rein, polyamides resin, siloxane resin, epoxy resin, and the like. These can be used alone or in combination with each other.

Accordingly, the transistor TR including the active layer ACT, the gate electrode GAT, the first electrode CE1, and the second electrode CE2 may be formed on the substrate SUB. The transistor TR of FIG. 4 may correspond to the first transistor T1 of FIG. 2.

The pixel electrode PE may be disposed on the third insulating layer IL3. The pixel electrode PE may be connected to the first electrode CE1 through a contact hole penetrating a part of the third insulating layer IL3. The pixel electrode PE may be a reflective, semi-transmissive, or transmissive electrode. For example, the pixel electrode PE may include metal, alloy, metal nitride, conductive metal oxide, transparent conductive material, and the like. These can be used alone or in combination with each other.

The pixel defining layer PDL may be disposed on the third insulating layer IL3. The pixel defining layer PDL may cover the edge of the pixel electrode PE. In addition, an opening exposing a part of an upper surface of the pixel electrode PE may be defined in the pixel defining layer PDL. For example, the pixel defining layer PDL may include an inorganic material or an organic material. In an embodiment, the pixel defining layer PDL may include an organic material such as epoxy resin, siloxane resin, and the like. These can be used alone or in combination with each other. In another embodiment, the pixel defining layer PDL may include an organic material containing a light blocking material such as black pigment, black dye, and the like.

The light emitting layer EML may be disposed on the pixel electrode PE. The light emitting layer EML may include an organic material that emits light of a preset color. For example, the light emitting layer EML may include an organic material that emits at least one of red light, green light, and blue light.

The common electrode CME may be disposed on the pixel defining layer PDL and the emitting layer EML. The common electrode CME may be disposed on the entire surface of the display area (e.g., the display area DA of FIG. 1). The common electrode CME may be a reflective, semi-transmissive, or transmissive electrode. For example, the common electrode CME may include metal, alloy, metal nitride, conductive metal oxide, transparent conductive material, and the like. These can be used alone or in combination with each other.

Accordingly, the light emitting element EL including the pixel electrode PE, the light emitting layer EML, and the common electrode CME may be formed in the display area on the substrate SUB. The light emitting element EL of FIG. 4 may correspond to the light emitting element LED of FIG. 2.

The encapsulation layer ENC may be disposed on the common electrode CME. The encapsulation layer ENC can prevent impurities, moisture, external air, etc. from penetrating into the light emitting element EL from the outside. The encapsulation layer ENC may include at least one inorganic layer and at least one organic layer. For example, the inorganic layer may include silicon oxide, silicon nitride, silicon oxynitride, and the like. These can be used alone or in combination with each other. The organic layer may include a cured polymer such as polyacrylate and the like.

FIG. 5 is a plan view illustrating an example of a test circuit disposed in a test area of FIG. 1.

Referring to FIGS. 1 and 5, the test circuit TC may be disposed in the test area TA. The test circuit TC may include a test gate driver GDV_T, a metal pattern MP, a plurality of test gate lines GL1_T to GLn_T, a first test gate pad TGP1, and a second test gate pad TGP2 (where, n is a natural number greater than 1).

The test area TA may include a first area A1 and a second area A2. The second area A2 may be positioned adjacent to the first area A1.

The test gate driver GDV_T may be disposed in the second area A2. The plurality of test gate lines GL1_T to GLn_T may be electrically connected to the test gate driver GDV_T. Accordingly, the test gate driver GDV_T may apply a test gate signal to the plurality of test gate lines GL1_T to GLn_T. A detailed description of the test gate driver GDV_T will be described later.

The metal pattern MP may be disposed in the first area A1. The metal pattern MP may overlap the plurality of test gate lines GL1_T to GLn_T in the plan view. Accordingly, each of the plurality of test gate lines GL1_T to GLn_T may form a capacitor together with the metal pattern MP.

In an embodiment, the metal pattern MP may include a plurality of sub-patterns S-MP connected to each other and overlapping the plurality of test gate lines GL1_T to GLn_T, respectively, in the plan view. Each of the plurality of sub-patterns S-MP may extend along the first direction DR1, and the plurality of sub-patterns S-MP may be arranged along the second direction DR2. In another embodiment, the metal pattern MP may be disposed as a plate.

In an embodiment, the metal pattern MP may be disposed in the same layer as the lower metal layer BML of FIG. 4. That is, the metal pattern MP may be formed using the same material as the lower metal layer BML of FIG. 4 and through the same process as the lower metal layer BML of FIG. 4. However, embodiments of the present disclosure are not limited thereto.

Each of the plurality of test gate lines GL1_T to GLn_T may include a first metal line ML1, and a second metal line ML2 connected to the first metal wire ML1. The second metal line ML2 may be adjacent to the first metal line ML1 in the first direction DR1. In an embodiment, the first metal line ML1 may be connected in series with the second metal line ML2. Specifically, the first metal line ML1 may be connected to the second metal line ML2 through a contact hole CNT.

In an embodiment, the first metal line ML1 may be directly connected to the test gate driver GDV_T. Specifically, the first metal line ML1 may be directly connected to each of the plurality of test stages ST1_T to STn_T included in the test gate driver GDV_T (where n is a natural number greater than 1).

The first metal line ML1 may be disposed in the same layer as the gate electrode GAT of FIG. 4. That is, the first metal line ML1 may be formed using the same material through the same process as the gate electrode GA of FIG. 4. However, embodiments of the present disclosure are not limited thereto. In an embodiment, the first metal line ML1 may include a relatively low-resistance metal material compared to the second metal line.

The second metal line ML2 may be disposed in the same layer as the active layer ACT of FIG. 4. That is, the second metal line ML2 may be formed using the same material as the active layer ACT of FIG. 4 through the same process as the active layer ACT of FIG. 4. However, embodiments of the present disclosure are not limited thereto. In an embodiment, the second metal line ML2 may include a metal oxide semiconductor. For example, the second metal line ML2 may include a metal oxide semiconductor doped with N-type impurities. Alternatively, the second metal line ML2 may include a metal oxide semiconductor doped with P-type impurities.

As a result, the resistance of the second metal line ML2 may be greater than the resistance of the first metal line ML1. As the first metal line ML1 is connected in series with the second metal line ML2, the resistance of each of the plurality of test gate lines GL1_T to GLn_T may be calculated as the sum of the resistance of the first metal line ML1 and the resistance of the second metal line ML2.

In this case, by adjusting a length L2 of the second metal line ML2 in the first direction DR1, the resistance of the plurality of test gate lines GL1_T to GLn_T may be made to have substantially the same resistance as the resistance of the plurality of gate lines GL1 to GLn of FIG. 1. Even if a second length L2 of the second metal line ML2 is adjusted, the sum of the first length L1 of the part of the first metal line ML1 overlapping the metal pattern MP in the plan view and the second length L2 of the second metal line ML2 may be constant.

A width of each of the plurality of test gate lines GL1_T to GTn_T may be constant in the first direction DR1. That is, in an embodiment, a first width W1 of the first metal line ML1 in the second direction DR2 may be the same as a second width W2 of the second metal line ML2 in the second direction DR2. However, embodiments of the present disclosure are not limited thereto.

The first length L1 of the part of the first metal line ML1 in the first direction DR1 may be different from the second length L2 of the part of the second metal line ML2 in the first direction DR1. In an embodiment, the first length L1 of the part of the first metal line ML1 in the first direction DR1 may be longer than the second length L2 of the part of the second metal line ML2 in the first direction DR1. In another embodiment (not shown), the first length L1 of the part of the first metal line ML1 in the first direction DR1 may be shorter than the second length L2 of the part of the second metal line ML2 in the first direction DR1.

The first test gate pad TGP1 may be connected to at least one first metal line ML1 among the plurality of test gate lines GL1_T to GTn_T, and the second test gate pad TGP2 may be connected to at least one second metal line ML2 among the plurality of test gate lines GL1_T to GTn_T. For example, the first test gate pad TGP1 may be connected to the first metal line ML1 of the n-th test gate line GLn_T, and the second test gate pad TGP2 may be connected to the second metal line ML2 of the n-th test gate line GLn_T.

The test gate signal may be applied to the first test gate pad TGP1 before the test gate signal is applied to the first metal line ML1, and the test gate signal passing through the second metal line ML2 may be applied to the second test gate pad TGP2.

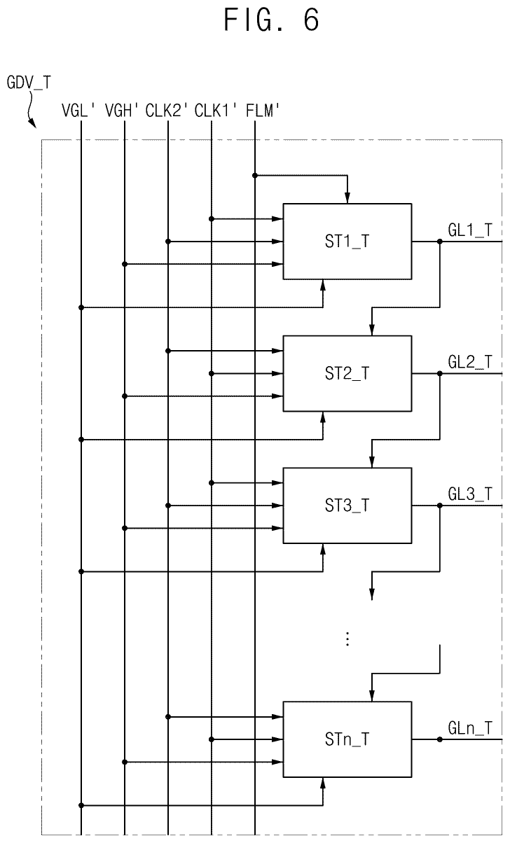

FIG. 6 is a view illustrating a test gate driver of FIG. 5.

Referring to FIG. 6, the test gate driver GDV_T may include a plurality of test stages ST1_T to STn_T. For example, the plurality of test stages ST1_T to STn_T may be connected to the plurality of test gate lines GL1_T to GLn_T, respectively (where n is a natural number greater than 1).

The plurality of test stages ST1_T to STn_T may output a plurality of test gate signals in response to a first voltage VGL′, a second voltage VGH′, at least one clock signal CLK1′ and CLK2′, and a test gate start signal FLM′. The plurality of test gate signals may be applied to the plurality of test gate lines GL1_T to GLn_T, respectively. The test gate start signal FLM′ may be applied to the first test stage ST1_T.

That is, the test gate driver GDV_T may be substantially the same as or similar to the gate driver GDV of FIG. 3.

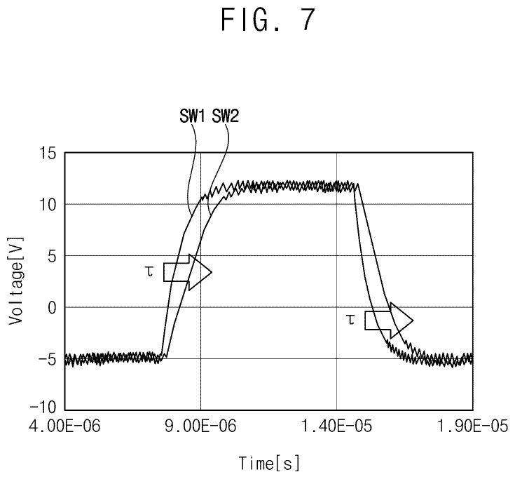

FIG. 7 is a graph illustrating waveform of a test gate signal applied to each of the first and second test gate pads of FIG. 5. For example, a first signal waveform SW1 of FIG. 7 is the waveform of the test gate signal applied to the first test gate pad TGP1, and a second signal waveform SW2 is the waveform of the test gate signal applied to the second test gate pad TGP2.

Referring to FIGS. 5 and 7, the test gate signal applied to the second test gate pad TGP2 may be delayed by t compared to the test gate signal applied to the first test gate pad TGP1 due to signal delay (RC delay). The signal delay can be expressed by Equation 1 below.

$$τ = R \times C \qquad [ Equation 1 ]$$

Here, t is the signal delay, R is the resistance of one test gate line, and C is the capacitance of the capacitor composed of the metal pattern MP and the one test gate line.

In Equation 1, R can be expressed by Equation 2 below.

$$\begin{matrix}R = {R}_{1} + {R}_{2} \\ = {R}_{S 1} \times ( L 1 / W ) + {R}_{S 2} \times ( L 2 / W ) \\ = ( {R}_{S 1} \times ( m \times h - L 2 ) + {R}_{S 2} \times L 2 ) / W \\ = L 2 \times ( {R}_{S 2} \times {R}_{S 1} ) + {R}_{S 1} \times m \times h\end{matrix} \qquad [ Equation 2 ]$$

Here, R₁ is the resistance of the first metal line ML1, R₂ is the resistance of the second metal line ML2, W is the width of the test gate line (e.g., W1 or W2 of FIG. 5), L1 is the first length of the first metal line ML1 (e.g., L1 of FIG. 5), L2 is the second length of the second metal line ML2 (e.g., L2 of FIG. 5), R_{S1} is the sheet resistance of the first metal line ML1, R_{S2} is the sheet resistance of the second metal line ML2, m is the number of a plurality of pixels (e.g., parts of the metal pattern MP that have the same width as the width W_P of each of the plurality of pixels PX of FIG. 1 and are spaced apart from each other) connected to one gate line (e.g., one among GL1 to GLn of FIG. 1), and h is the width of each of the plurality of pixels (e.g., W_P of FIG. 1). In addition, the sum of L1 and L2 is equal to (or similar to) the product of m and h.

In Equation 1, C can be expressed by Equation 3 below.

$$\begin{matrix}C = W \times ( ε 1 / d 1 \times L 1 + ε 2 / d 2 \times L 2 ) \\ = W \times ( ε 1 / d 1 \times ( m \times h - L 1 ) + ε 2 / d 2 \times L 2 ) \\ = ϵ / d \times W \times m \times h\end{matrix} \qquad [ Equation 2 ]$$

Here, W is the width of the test gate line (e.g., W1 or W2 of FIG. 5), ε1 is the dielectric constant of a first part of an insulating film, &2 is the dielectric constant of a second part of the insulating film, d1 is the thickness of the first part of the insulating film, and d2 is the thickness of the second part of the insulating film. The thickness of each of the first part and the second part is the thickness in a third direction (i.e., the third direction DR3 of FIG. 4). The third direction may be perpendicular to the plane defined by the first direction DR1 and the second direction DR2 of FIG. 1.

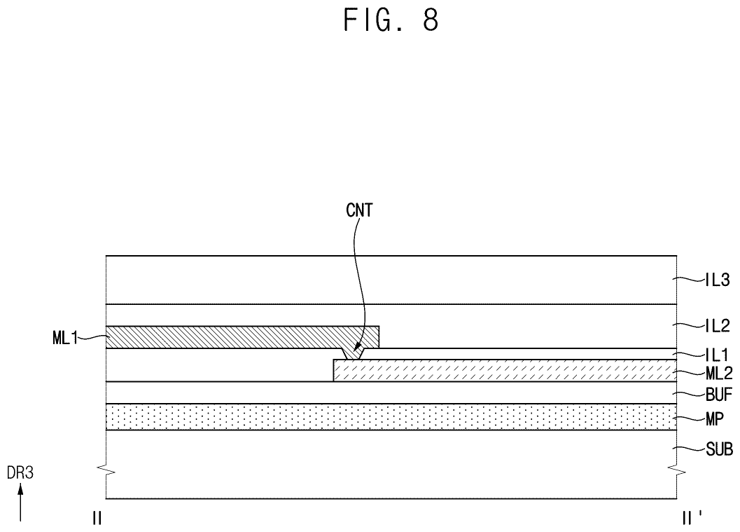

The first part is a part of the buffer layer BUF and the first insulating layer IL1 between the metal pattern MP and the first metal line ML1 of FIG. 8, and the second part is a part of the buffer layer BUF between the metal pattern MP and the second metal line ML2 of FIG. 8. In addition, ε1/d1 is the same as (or similar to) ε2/d2. The sum of L1 and L2 is equal to (or similar to) the product of m and h.

FIG. 8 is a cross-sectional view illustrating an example of a cross-section taken along line II-II′ of FIG. 5.

Referring to FIG. 8, in an embodiment, the first metal line ML1 may be directly connected to the second metal line ML2 through a contact hole penetrating a part of the first insulating layer IL1.

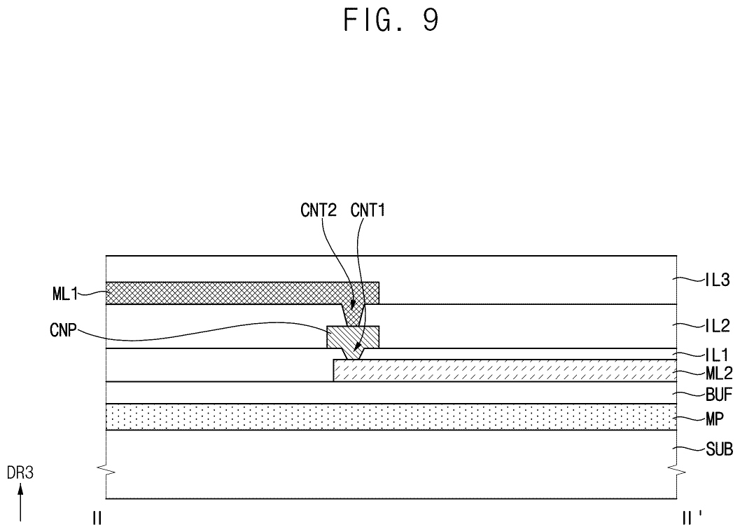

FIG. 9 is a cross-sectional view illustrating another example of a cross-section taken along line II-II′ of FIG. 5.

Referring to FIG. 9, in an embodiment, the first metal line ML1 may be directly connected to a connection pattern CNP through a second contact hole CNT2 penetrating a part of the second insulating layer IL2, and the connection pattern CNP may be directly connected to the second metal line ML2 through a first contact hole CNT1 penetrating a part of the first insulating layer IL1. That is, in this case, the first metal line ML1 may be connected to the second metal line ML2 through the connection pattern CNP.

The connection pattern CNP may be disposed in the same layer as the gate electrode GAT of FIG. 4. That is, the connection pattern CNP can be formed through the same process using the same material as the gate electrode GAT of FIG. 4. The first metal line ML1 may be disposed in the same layer as the first electrode CE1 and the second electrode CE2 of FIG. 4. That is, the first metal line ML1 may be formed using the same material and through the same process as the first electrode CE1 and the second electrode CE2 of FIG. 4.

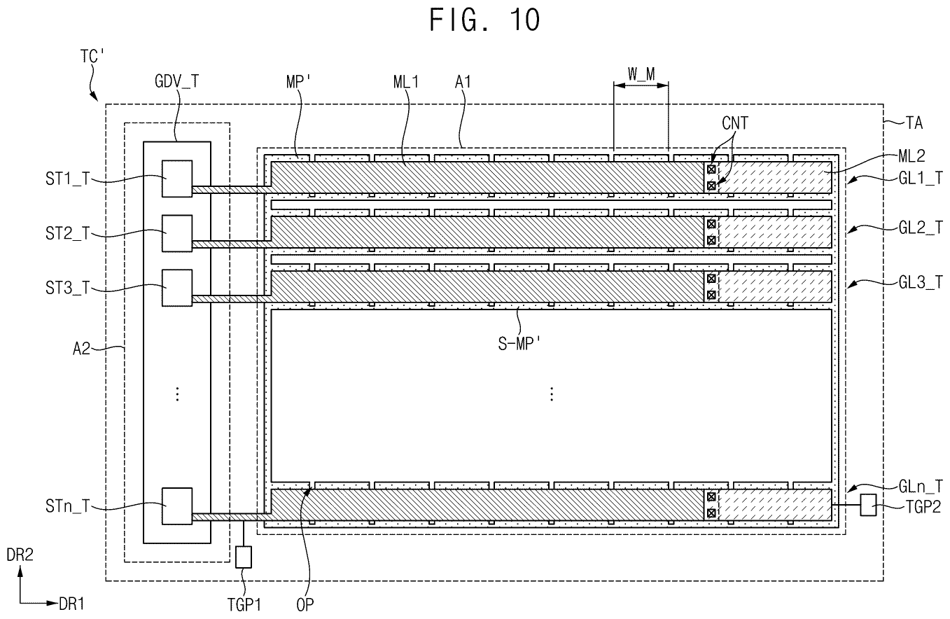

FIG. 10 is a plan view illustrating another example of a test circuit disposed in a test area of FIG. 1.

Referring to FIGS. 1 and 10, a test circuit TC′ may be disposed in the test area TA. The test circuit TC′ may include a test gate driver GDV_T, a metal pattern MP′, a plurality of test gate lines GL1_T to GLn_T, a first test gate pad TGP1, and a second test gate pad TGP2 (where, n is a natural number greater than 1). However, the test circuit TC′ described with reference to FIG. 10 may be substantially the same or similar to the test circuit TC described with reference to FIG. 5 except for the metal pattern MP′. Hereinafter, overlapping descriptions are omitted or simplified.

The test area TA may include a first area A1 and a second area A2. The second area A2 may be positioned adjacent to the first area A1.

The metal pattern MP′ may be disposed in the first area A1. The metal pattern MP′ may include a plurality of sub-patterns S-MP′ connected to each other and overlapping the plurality of test gate lines GL1_T to GLn_T, respectively, in the plan view. Each of the plurality of sub-patterns S-MP′ may extend along the first direction DR1, and the plurality of sub-patterns S-MP′ may be arranged along the second direction DR2.

In an embodiment, a plurality of openings OP arranged along the first direction DR1 may be defined in each of the plurality of sub-patterns S-MP′. Here, a width W_M of the part of the metal pattern MP′ positioned between two adjacent openings OP may be substantially the same as the width W_P of one pixel PX of FIG. 1.

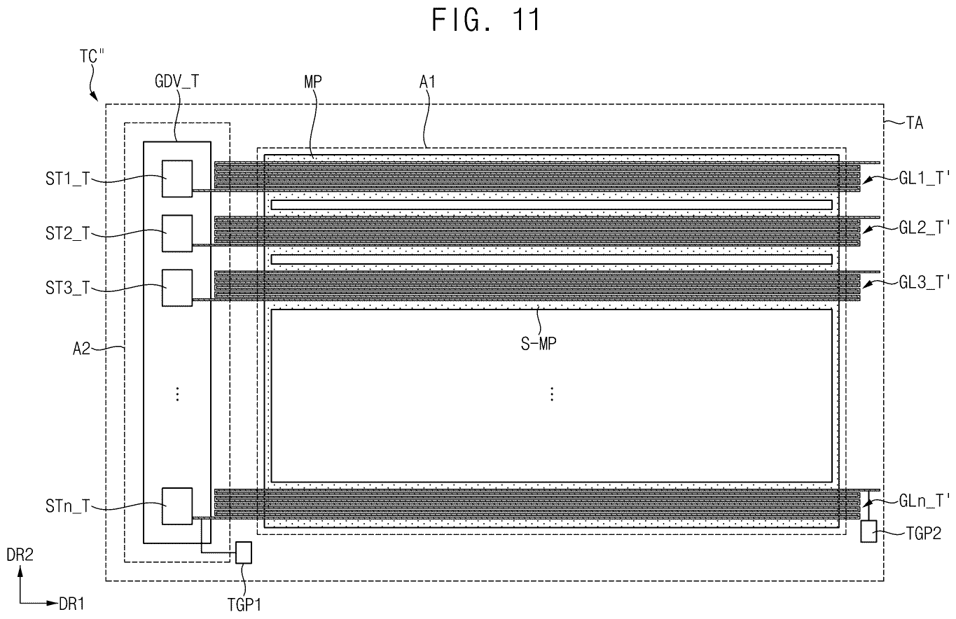

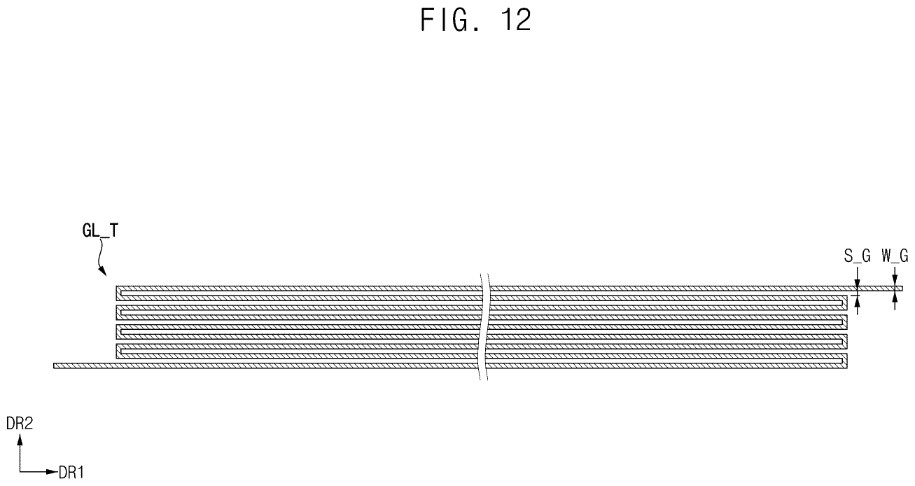

FIG. 11 is a plan view illustrating still another example of a test circuit disposed in a test area of FIG. 1. FIG. 12 is a plan view for explaining a test gate line of FIG. 11.

Referring to FIGS. 1, 11, and 12, a test circuit TC″ may be disposed in the test area TA. The test circuit TC″ may include a test gate driver GDV_T, a metal pattern MP′, a plurality of test gate lines GL1_T′ to GLn_T′, a first test gate pad TGP1, and a second test gate pad TGP2 (where, n is a natural number greater than 1). However, the test circuit TC″ described with reference to FIGS. 11 and 12 may be substantially the same or similar to the test circuit TC described with reference to FIG. 5 except for the plurality of test gate lines GL1_T′ to GLn_T′. Hereinafter, overlapping descriptions are omitted or simplified.

The test area TA may include a first area A1 and a second area A2. The second area A2 may be positioned adjacent to the first area A1.

The test gate driver GDV_T may be disposed in the second area A2. The plurality of test gate lines GL1_T′ to GLn_T′ may be electrically connected to the test gate driver GDV_T.

Specifically, the plurality of test gate lines GL1_T′ to GLn_T′ may be connected to the plurality of test stages ST1_T to STn_T included in the test gate driver GDV_T, respectively. The plurality of test gate lines GL1_T′ to GLn_T′ may each receive a test gate signal through the plurality of test stages ST1_T to STn_T.

The metal pattern MP may be disposed in the first area A1. The metal pattern MP may overlap the plurality of test gate lines GL1_T to GLn_T in the plan view. Accordingly, each of the plurality of test gate lines GL1_T′ to GLn_T′ may form a capacitor together with the metal pattern MP.

In an embodiment, the metal pattern MP may include a plurality of sub-patterns S-MP connected to each other and overlapping the plurality of test gate lines GL1_T′ to GLn_T′, respectively, in the plan view. Each of the plurality of sub-patterns S-MP may extend along the first direction DR1, and the plurality of sub-patterns S-MP may be arranged along the second direction DR2. In another embodiment, the metal pattern MP may be disposed as a plate.

In an embodiment, each of the plurality of test gate lines GL1_T′ to GLn_T′ may have a zigzag shape in the plan view. That is, each of the plurality of test gate lines GL1_T′ to GLn_T′ has a shape that repeatedly passes through the first area A1 in the first direction DR1 and in a direction opposite to the first direction DR1 in the plan view.

A width W_G of each of the plurality of test gate lines GL1_T′ to GLn_T′ in the second direction DR2 may have a constant value. In addition, a gap S_G between adjacent parts of each of the plurality of test gate lines GL1_T′ to GLn_T′ in the second direction DR2 may have a constant value.

Each of the plurality of test gate lines GL1_T′ to GLn_T′ may be disposed in the same layer as the gate electrode GAT of FIG. 4. That is, each of the plurality of test gate lines GL1_T′ to GLn_T′ may be formed through the same process using the same material as the gate electrode GAT of FIG. 4. However, embodiments of the present disclosure are not limited thereto.

The first test gate pad TGP1 may be connected to at least one among the plurality of test gate lines GL1_T′ to GLn_T′, and the second test gate pad TGP2 may be connected to at least one among the plurality of test gate lines GL1_T′ to GLn_T′. For example, the first test gate pad TGP1 may be connected to one end of the n-th test gate line GLn_T′, and the second test gate pad TGP2 may be connected to the other end of the n-th test gate line GLn_T′.

In the case where each of the plurality of test gate lines GL1_T′ to GLn_T′ has a zigzag shape in the plan view, as shown in FIG. 7, the test gate signal applied to the second test gate pad TGP2 may be delayed by t compared to the test gate signal applied to the first test gate pad TGP1 due to signal delay.

The signal delay can be expressed by Equation 4 below.

$$τ = R \times C \qquad [ Equation 4 ]$$

Here, t is the signal delay, R is the resistance of one test gate line, and C is the capacitance of the capacitor composed of the metal pattern MP and the one test gate line.

In Equation 4, R can be expressed by Equation 5 below.

$$\begin{matrix}R = {R}_{S} \times L / W \\ = {R}_{S} \times ( m \times h \times r ) / W\end{matrix}$$

Here, R_{S} is the sheet resistance of one test gate line, L is the length of the one test gate line in the first direction DR1, and W is the width of the one test gate line (e.g., W_G of FIG. 12). In addition, m is the number of a plurality of pixels (e.g., parts of the metal pattern MP that have the same width as the width W_P of each of the plurality of pixels PX of FIG. 1 and are spaced apart from each other) connected to one gate line (e.g., one among GL1 to GLn of FIG. 1), h is the width of each of the plurality of pixels (e.g., W_P of 1), and r is the number of repetitions of the one test gate line.

For example, in the case of FIG. 12, the number of repetitions for each of the plurality of test gate lines GL1_T′ to GLn_T′ is 9. That is, the number of repetitions of each of the plurality of test gate lines GL1_T′ to GLn_T′ means that the number of patterns in which each of the plurality of test gate lines GL1_T′ to GLn_T′ overlaps the metal pattern MP in the plan view and extends in the direction DR1.

In Equation 4, C can be expressed by Equation 6 below.

$$\begin{matrix}C = ε / d \times W \times L \\ = ε / d \times W \times ( m \times h \times r )\end{matrix} \qquad [ Equation 6 ]$$

Here, & is the dielectric constant of an insulating film, d is the thickness of the insulating film, and L is the length of the one test gate line in the first direction DR1. The insulating film is part of a buffer layer (e.g., the buffer layer BUF of FIG. 8) between the metal pattern MP and the one test gate line. In addition, m is the number of a plurality of pixels (e.g., parts of the metal pattern MP that have the same width as the width W_P of each of the plurality of pixels PX of FIG. 1 and are spaced apart from each other) connected to one gate line (e.g., one among GL1 to GLn of FIG. 1), h is the width of each of the plurality of pixels (e.g., W_P of 1), and r is the number of repetitions of the one test gate line.

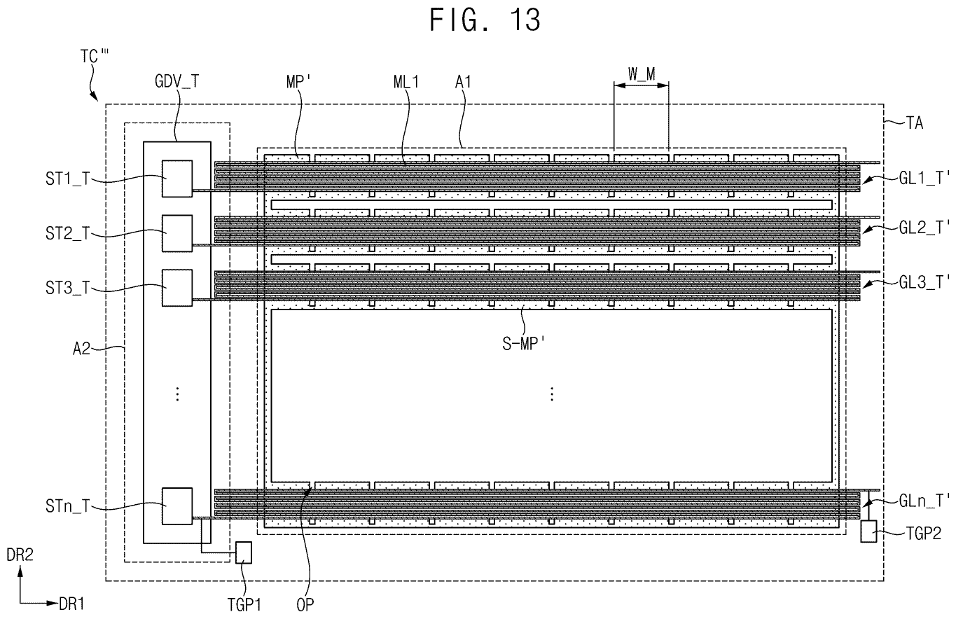

FIG. 13 is a plan view illustrating still another example of a test circuit disposed in a test area of FIG. 1.

Referring to FIGS. 1 and 13, a test circuit TC″ may be disposed in the test area TA. The test circuit TC″ may include a test gate driver GDV_T, a metal pattern MP′, a plurality of test gate lines GL1_T′ to GLn_T′, a first test gate pad TGP1, and a second test gate pad TGP2 (where, n is a natural number greater than 1). However, the test circuit TC″ described with reference to FIG. 13 may be substantially the same or similar to the test circuit TC″ described with reference to FIG. 11 except for the metal pattern MP′. Hereinafter, overlapping descriptions are omitted or simplified.

The test area TA may include a first area A1 and a second area A2. The second area A2 may be positioned adjacent to the first area A1.

The metal pattern MP′ may include a plurality of sub-patterns S-MP′ connected to each other and overlapping the plurality of test gate lines GL1_T to GLn_T, respectively, in the plan view. Each of the plurality of sub-patterns S-MP′ may extend along the first direction DR1, and the plurality of sub-patterns S-MP′ may be arranged along the second direction DR2.

In an embodiment, a plurality of openings OP arranged along the first direction DR1 may be defined in each of the plurality of sub-patterns S-MP′. Here, a width W_M of the part of the metal pattern MP′ positioned between two adjacent openings OP may be substantially same as the width W_P of one pixel PX of FIG. 1.

Referring again to FIGS. 1, 2, 3, 4, 5, 6, 7, 8, 9, 10, 11, 12, and 13, the test circuits TC, TC′, TC″, and TC″ according to embodiments of the present disclosure may includes the plurality of test gate lines GL1_T to GLn_T connected to the test gate driver GDV_T and that receives the test gate signal, and each including the first metal line ML1 and the second metal line ML2 connected in series with the first metal line ML1. Alternatively, each of the plurality of test gate lines GL1_T to GLn_T may have a zigzag shape in a plan view. Accordingly, a load corresponding to resistance and capacitance substantially equivalent to the display area DA may be reflected in the test circuit TC, TC′, TC″, and TC″. In this case, it can be possible to implement a waveform of the test gate signal that is substantially equivalent to the gate signal applied to the pixel PX.

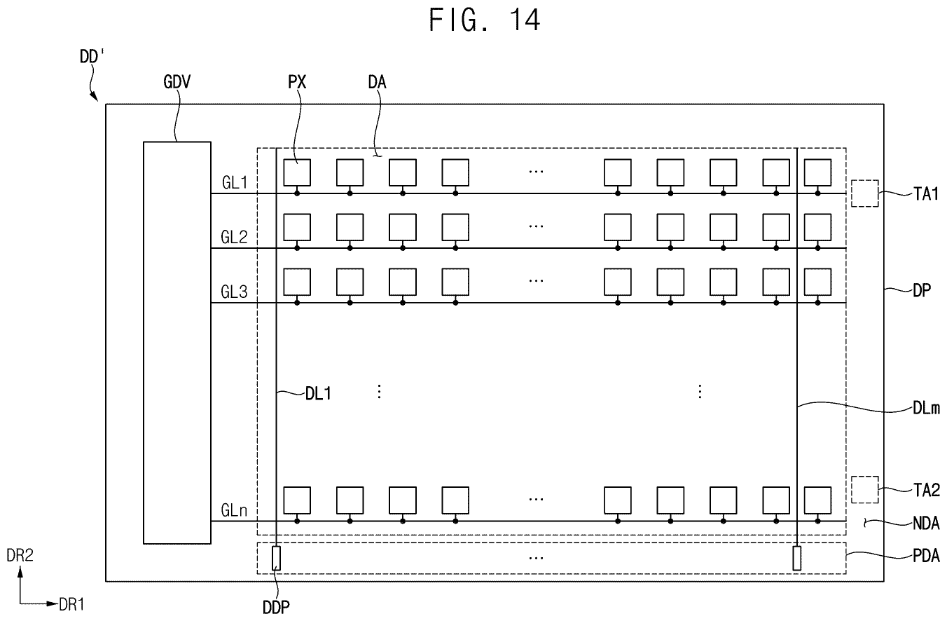

FIG. 14 is a block diagram schematically illustrating a display device according to another embodiment of the present disclosure.

Referring to FIG. 14, a display device DD′ according to an embodiment of the present disclosure may include a display panel DP, a plurality of data pads DDP, a plurality of data lines DL1 to DLm, a gate driver GDV, a plurality of gate lines GL1 to GLn, and a plurality of pixels PX. Hereinafter, descriptions that overlap with those of the display device DD described with reference to FIG. 1 will be omitted or simplified.

The display panel DP may include a display area DA and a non-display area NDA. The non-display area NDA may surround at least a part of the display area DA.

The non-display area NDA may include at least one first test area TA1 and at least one second test area TA2. Each of the first and second test areas TA1 and TA2 may be positioned away from one side of the display area DA. The positions of the first and second test areas TA1 and TA2 shown in FIG. 14 are examples, and embodiments of the present disclosure are not limited thereto.

As shown in FIG. 14, the number of each of the first and second test area TA1 and TA2 is one. Alternatively, each of the first and second test areas TA1 and TA2 may be plural.

A first test circuit may be disposed in the first test area TA1. The first test circuit may correspond to the test circuit TC of FIG. 5 or the test circuit TC′ of FIG. 10. That is, the first test circuit may include a first metal pattern disposed in a first area of the first test area TA1, a first test gate driver disposed in a second area adjacent to the first area and including a plurality of test stages that each outputs a first test gate signal, and a plurality of test gate lines overlapping the first metal pattern in a plan view, connected to the plurality of test stages of the first test gate driver, respectively, and that receives the first test gate signal, and each including a first metal line and a second metal line connected in series with the first metal line.

A second test circuit may be disposed in the second test area TA2. The second test circuit may correspond to the test circuit TC″ of FIG. 11 or the test circuit TC″ of FIG. 13. That is, the second test circuit may include a second metal pattern disposed in a third area of the second test area TA2, a second test gate driver disposed in a fourth area adjacent to the third area and including a plurality of test stages that each outputs a second test gate signal, and a plurality of test gate lines overlapping the second metal pattern in a plan view, connected to the plurality of test stages of the second test gate driver, respectively, and that receives the second test gate signal, and each having a zigzag shape in the plan view.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A test circuit comprising:
a metal pattern disposed in a first area;
a test gate driver disposed in a second area adjacent to the first area and including a plurality of test stages, each of which outputs a test gate signal; and
a plurality of test gate lines overlapping the metal pattern in a plan view, connected to the plurality of test stages, respectively, each including a first metal line and a second metal line connected in series with the first metal line, and which receives the test gate signal.

2. The test circuit of claim 1, wherein a resistance of the second metal line is greater than a resistance of the first metal line.

3. The test circuit of claim 1, wherein the first metal line includes a relatively low-resistance metal material compared to the second metal line.

4. The test circuit of claim 1, wherein the second metal line includes a metal oxide semiconductor.

5. The test circuit of claim 4, wherein the first metal line is directly connected to each of the plurality of test stages.

6. The test circuit of claim 1, wherein the second metal line includes a metal oxide semiconductor doped with an N-type impurity.

7. The test circuit of claim 1, wherein the first metal line is connected to the second metal line through a contact hole.

8. The test circuit of claim 1, wherein the first metal line is adjacent to the second metal line in a first direction,
a first width of a part of the first metal line overlapping the metal pattern is the same as a second width of the second metal line, and
the first width and the second width are measured in a second direction crossing the first direction.

9. The test circuit of claim 8, wherein a first length of the part of the first metal line overlapping the metal pattern is different from a second length of the second metal line, and the first length and the second length are measured in the first direction.

10. The test circuit of claim 9, wherein the first length is longer than the second length.

11. The test circuit of claim 9, wherein the first length is shorter than the second length.

12. The test circuit of claim 1, wherein the metal pattern includes a plurality of sub-patterns connected to each other and overlapping the plurality of test gate lines in the plan view, respectively.

13. The test circuit of claim 1, wherein the metal pattern includes a plurality of sub-patterns connected to each other, overlapping the plurality of test gate lines in the plan view, respectively, and arranged along a first direction, and
a plurality of openings arranged along a second direction crossing the first direction are defined in each of the plurality of sub-patterns in the plan view.

14. A test circuit comprising:
a metal pattern disposed in a first area;
a test gate driver disposed in a second area adjacent to the first area and including a plurality of test stages, each of which outputs a test gate signal; and
a plurality of test gate lines overlapping the metal pattern in a plan view, connected to the plurality of test stages, respectively, each having a zigzag shape in the plan view, and which receives the test gate signal.

15. The test circuit of claim 14, wherein the metal pattern includes a plurality of sub-patterns connected to each other and overlapping the plurality of test gate lines in the plan view, respectively.

16. The test circuit of claim 14, wherein the metal pattern includes a plurality of sub-patterns connected to each other, overlapping the plurality of test gate lines in the plan view, respectively, and arranged along a first direction, and
a plurality of openings arranged along a second direction crossing the first direction are defined in each of the plurality of sub-patterns in the plan view.

17. A display device comprising:
a display panel including a display area in which a plurality of pixels are disposed, and a non-display area surrounding at least a part of the display area and including a first test area;
a gate driver disposed in the non-display area and, which applies a gate signal to the plurality of pixels; and
a first test circuit disposed in the first test area and including:
a first metal pattern disposed in a first area of the first test area;
a first test gate driver disposed in a second area of the first test area adjacent to the first area and including a plurality of test stages, each of which outputs a first test gate signal; and
a plurality of first test gate lines overlapping the first metal pattern in a plan view, connected to the plurality of test stages, respectively, each including a first metal line and a second metal line connected in series with the first metal line, and which receives the first test gate signal.

18. The display device of claim 17, wherein the first metal line is directly connected to each of the plurality of test stages, and the second metal line includes a metal oxide semiconductor.

19. The display device of claim 17, wherein the first metal line is connected to the second metal line through a contact hole.

20. The display device of claim 17, further comprising:
a second test circuit disposed in a second test area positioned in the non-display area and including a third area and a fourth area, and including:
a second metal pattern disposed in the third area of the second test area;
a second test gate driver disposed in the fourth area of the second test area adjacent to the third area and including a plurality of test stages, each of which outputs a second test gate signal; and
a plurality of test gate lines overlapping the second metal pattern in the plan view, connected to the plurality of test stages of the second test gate driver, respectively, each having a zigzag shape in the plan view, and which receives the second test gate signal.
